(19) United States
(12) Patent Application Publication
(10) Pub. No.: US 2025/0176200 A1
(43) Pub. Date: May 29, 2025

(54) Semiconductor Structure and Manufacturing Method Thereof

(71) Applicant: Diodes Incorporated, Plano, TX (US)

(72) Inventors: Tao Long, Shanghai (CN); Pin-Hao Huang, New Taipei City (TW); Ze Rui Chen, Plano, TX (US)

(21) Appl. No.: 18/952,927

(22) Filed: Nov. 19, 2024

(30) Foreign Application Priority Data
Nov. 24, 2023 (CN) 202311595150.7

(51) Int. Cl. H01L 29/872; H01L 29/06

(52) U.S. Cl. CPC H10D 8/605; H10D 62/106

(57) ABSTRACT

A semiconductor structure includes a substrate comprising a first surface and a second surface positioned on an opposite side of the substrate. A first trench structure extends from the first surface toward the second surface, wherein the first trench structure comprises a first polysilicon structure and a first oxide layer surrounding the first polysilicon structure. A shielding metal layer is located on the first surface of the substrate and covers the first trench structure. A first conductive layer is disposed on the shielding metal layer, and a second conductive layer is disposed on the second surface of the substrate. The substrate comprises a first doped region located between the first surface and the second surface, adjacent to the first oxide layer and separated from the first polysilicon structure.

### CROSS-REFERENCE TO RELATED APPLICATIONS

This patent application claims priority to Chinese Patent Application No. CN 202311595150.7, filed on Nov. 24, 2023, and entitled “Semiconductor Structure and Manufacturing Method Thereof,” which is hereby incorporated by reference herein as if reproduced in its entirety.

### TECHNICAL FIELD

The present disclosure relates generally to the field of semiconductors, and in particular embodiments, to a semiconductor structure and a manufacturing method thereof. Particular embodiments provide a trench-type Metal-Oxide-Semiconductor (MOS) rectifier device and a manufacturing method thereof.

### BACKGROUND

Modern power circuits require rectifiers with high power, low loss, and fast switching capabilities. For high-voltage applications, P-N junction rectifiers with high switching speed are often used when high breakdown voltage and high operating temperatures are required. For low-voltage applications, Schottky barrier rectifiers are often used when high switching speed and very low forward voltage (forward bias) are needed. Schottky barrier rectifiers are majority carrier devices that use Metal-Oxide-Semiconductor (MOS) processes, allowing very small reverse leakage currents during recovery. Unfortunately, at elevated temperatures, Schottky barrier rectifiers experience undesirably high reverse leakage currents.

Some improvements have been adopted to enhance the blocking capability of Schottky rectifiers. One such improvement involves the use of Schottky Barrier Diodes (SBD), which have a lower forward voltage, favoring reduced forward power loss. However, SBDs also have higher reverse leakage currents, leading to higher reverse power loss, which becomes a technical bottleneck for such devices. Due to the Schottky barrier lowering effect, the leakage current in Schottky rectifiers is influenced by the electric field at the metal-semiconductor interface.

Therefore, further improvements are needed in rectifier devices within existing technology to achieve better high power, low loss performance, and to make them suitable for fast switching applications.

### SUMMARY

Technical advantages are generally achieved, by embodiments of this disclosure which describe innovative semiconductor structures and manufacturing methods thereof.

The embodiments of the present disclosure relate to a semiconductor structure. The semiconductor structure comprises a substrate comprising a first surface and a second surface relative to the first surface; a first trench structure extending from the first surface toward the second surface, wherein the first trench structure comprises a first polysilicon structure and a first oxide layer surrounding the first polysilicon structure; a shielding metal layer located on the first surface of the substrate and covering the first trench structure; a first conductive layer disposed on the shielding metal layer; and a second conductive layer disposed on the second surface of the substrate, wherein the top surfaces of the first polysilicon structure and the first oxide layer are coplanar with the first surface.

The embodiments of the present disclosure also relate to a semiconductor structure. The semiconductor structure comprises a substrate comprising a first surface and a second surface positioned on an opposite side of the substrate; a first trench structure extending from the first surface toward the second surface, wherein the first trench structure comprises a first polysilicon structure and a first oxide layer surrounding the first polysilicon structure; a shielding metal layer located on the first surface of the substrate and covering the first trench structure; a first conductive layer disposed on the shielding metal layer; and a second conductive layer disposed on the second surface of the substrate, wherein the substrate comprises a first doped region located between the first surface and the second surface, adjacent to the first oxide layer and separated from the first polysilicon structure.

The embodiments of the present disclosure also relate to a method for manufacturing a semiconductor structure. The method comprises forming a first trench and a second trench in a substrate, wherein the first trench and the second trench are spaced apart and extend from a first surface of the substrate toward a second surface of the substrate located on an opposite side of the substrate; forming a first oxide layer in the first trench; forming a second oxide layer in the second trench; forming a first polysilicon structure in the first trench, wherein the first polysilicon structure is surrounded by the first oxide layer, and the first polysilicon structure and the first oxide layer form a first trench structure; and forming a second polysilicon structure in the second trench, wherein the second polysilicon structure is surrounded by the second oxide layer, and the second polysilicon structure and the second oxide layer form a second trench structure.

The foregoing has outlined rather broadly the features and technical advantages of the present disclosure in order that the detailed description of the disclosure that follows may be better understood. Additional features and advantages of the disclosure will be described hereinafter which form the subject of the claims of the disclosure. It should be appreciated by those skilled in the art that the conception and specific embodiment disclosed may be readily utilized as a basis for modifying or designing other structures or processes for carrying out the same purposes of the present disclosure. It should also be realized by those skilled in the art that such equivalent constructions do not depart from the spirit and scope of the disclosure as set forth in the appended claims.

### BRIEF DESCRIPTION OF THE DRAWINGS

For a more complete understanding of the present disclosure, and the advantages thereof, reference is now made to the following descriptions taken in conjunction with the accompanying drawings. It is important to acknowledge that the proportional representation of various structures may not be strictly adhered to. In practice, for the sake of elucidation, the dimensions of these structures may be deliberately exaggerated or minimized to enhance clarity in explanation.

FIG. 1 is a cross-sectional view illustrating an exemplary semiconductor structure in accordance with various embodiments of the present disclosure;

FIG. 2 is a cross-sectional view illustrating an exemplary semiconductor structure in accordance with various embodiments of the present disclosure;

FIG. 3 is a graph showing the depth-to-electric field relationship of an exemplary semiconductor structure in accordance with various embodiments of the present disclosure; and

FIG. 4 to FIG. 19 depict one or more stages in a manufacturing method of a semiconductor structure in accordance with various embodiments of the present disclosure.

Identical or similar components are denoted by the same reference numbers in the figures and detailed description. From the following detailed description in conjunction with the accompanying drawings, several embodiments of the present disclosure will be readily understood.

### DETAILED DESCRIPTION OF ILLUSTRATIVE EMBODIMENTS

The following disclosure provides numerous different embodiments or examples for implementing the various features of the provided subject matter. Specific instances of components and configurations are described below. Of course, these are merely examples and are not intended to limit the scope of the present disclosure. In this disclosure, references to the formation of a first feature above or on top of a second feature may include embodiments where the first and second features are formed in direct contact, as well as embodiments where additional features are formed between the first and second features, allowing for cases where the first and second features do not directly contact each other. Additionally, the disclosure may repeat reference numerals and/or letters across various instances. This repetition is for simplicity and clarity and does not indicate any relationship between the various embodiments and/or configurations being discussed.

Further, it should be understood that various changes, substitutions and alterations can be made herein without departing from the spirit and scope of this disclosure as defined by the appended claims. One or more features from one or more of the following described embodiments may be combined to create alternative embodiments not explicitly described, and features suitable for such combinations are understood within the scope of this disclosure. It is therefore intended that the appended claims encompass any such modifications or embodiments.

The embodiments of the present disclosure are discussed in detail below. However, it should be understood that this disclosure offers many applicable concepts that can be embodied in a wide variety of specific environments. The specific embodiments discussed are merely illustrative and do not limit the scope of the present disclosure.

Embodiments of the present disclosure provide a semiconductor structure and manufacturing method thereof. In the embodiment semiconductor structure of this disclosure, the shapes and positions of the polysilicon structures and oxide layers within the trench structures make the silicon carbide substrate less prone to breakdown, thus achieving a higher operable forward voltage and breakdown voltage. Additionally, the embodiment semiconductor structure in this disclosure features a lower epitaxial concentration, resulting in a lower forward voltage drop during conduction, a lower surface electric field, and reduced leakage current.

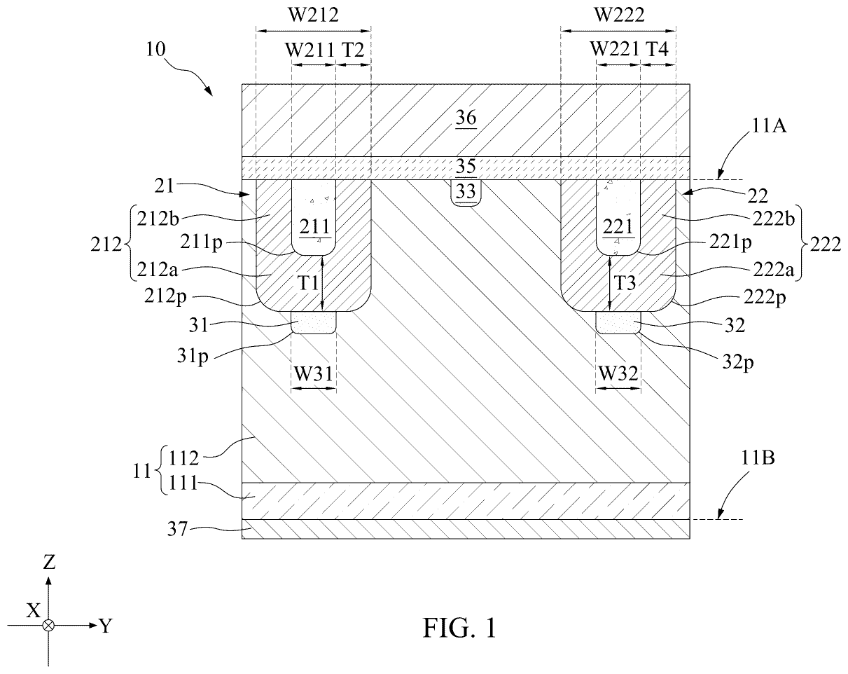

FIG. 1 shows a cross-sectional view of an example of a semiconductor structure 10 in accordance with various embodiments of the present disclosure. Specifically, the semiconductor structure 10 is a trench-type MOS rectifier device structure, with a vertical current conduction path. For example, current can vertically conduct through the semiconductor structure 10.

As shown in FIG. 1, the semiconductor structure 10 comprises a substrate 11, a first trench structure 21, and a second trench structure 22. Additionally, the semiconductor structure 10 may comprise a shielding metal layer 35, a first conductive layer 36, and a second conductive layer 37.

In some embodiments, the substrate 11 comprises a base material 111 and an epitaxial layer 112 positioned on the base material 111. In some embodiments, the base material 111 may include, for example, silicon, silicon carbide (SiC), germanium (Ge), silicon-germanium (SiGe), gallium nitride (GaN), gallium arsenide (GaAs), gallium arsenide phosphide (GaAsP), or other semiconductor materials. The epitaxial layer 112 may include, for instance, silicon, silicon carbide (SiC), germanium (Ge), silicon-germanium (SiGe), gallium nitride (GaN), gallium arsenide (GaAs), gallium arsenide phosphide (GaAsP), or other semiconductor materials. In some embodiments, the epitaxial layer 112 may include silicon carbide. The base material 111 may be an N-type or P-type semiconductor material. The epitaxial layer 112 may be an N-type or P-type semiconductor material.

The base material 111 and the epitaxial layer 112 have the same conductivity type doping. For example, both the base material 111 and the epitaxial layer 112 are N-type. In some embodiments, the base material 111 may be part of a silicon substrate or silicon wafer. The doping concentration of the base material 111 is greater than that of the epitaxial layer 112.

The substrate 11 may have a first surface 11A and a second surface 11B opposite to the first surface 11A. The second surface 11B and the first surface 11A can be located on opposite sides of the substrate 11. The first surface 11A and the second surface 11B may be horizontal planes. For ease of description, the direction perpendicular to the first surface 11A and second surface 11B is defined as the vertical direction Z, while the plane formed by the first direction X and second direction Y is perpendicular to the vertical direction Z. In some embodiments, the first surface 11A may be the active surface of the epitaxial layer 112. The bottom surface of the base material 111 may be the second surface 11B, which can be used to contact a metal layer, such as to contact the second conductive layer 37.

The first trench structure 21 extends from the first surface 11A toward the second surface 11B, where the first trench structure 21 comprises a first polysilicon structure 211 and a first oxide layer 212 surrounding the first polysilicon structure 211. In some embodiments, the top surface of the first trench structure 21 may be coplanar with the first surface 11A. In some embodiments, the top surfaces of the first polysilicon structure 211 and the first oxide layer 212 may be coplanar with the first surface 11A. From a top view, the first trench structure 21 extends along the first direction X, parallel to the first surface 11A.

The first oxide layer 212 is used to electrically isolate the first polysilicon structure 211 from the epitaxial layer 112. In other words, the first polysilicon structure 211 is separated from the epitaxial layer 112 via the first oxide layer 212 within the trench. The first oxide layer 212 surrounds the first polysilicon structure 211. The sidewalls and bottom wall of the first polysilicon structure 211 are in contact with the first oxide layer 212. The first oxide layer 212 includes a bottom wall portion 212a and a sidewall portion 212b, which is positioned above the bottom wall portion 212a and surrounds the first polysilicon structure 211. The first polysilicon structure 211 is positioned on the bottom wall portion 212a of the first oxide layer 212, and the sidewalls of the first polysilicon structure 211 are surrounded by the sidewall portion 212b of the first oxide layer 212. In some embodiments, the first polysilicon structure 211 is a columnar structure.

The thickness T1 of the bottom wall portion 212a and the thickness T2 of the sidewall portion 212b of the first oxide layer 212 can be adjusted based on the size of the first polysilicon structure 211 or the operating voltage. For example, the thickness T2 of the sidewall portion 212b of the first oxide layer 212 may be less than or equal to the width W211 of the first polysilicon structure 211 within the trench. The electrical stress of the first oxide layer 212 can be reduced by adjusting the thickness T1 of the bottom wall portion 212a of the first oxide layer 212, such as by making the thickness T1 of the bottom wall portion 212a greater than the thickness T2 of the sidewall portion 212b. In some embodiments, the first oxide layer 212 may contain silicon oxide. In some embodiments, the first polysilicon structure 211 may contain polysilicon material.

The substrate 11 may contain a first doped region 31, which extends in the first direction X. In some embodiments, the first doped region 31 may be positioned between the first surface 11A and the second surface 11B, adjacent to the first oxide layer 212 and separated from the first polysilicon structure 211. In some embodiments, the first doped region 31 may be located within the epitaxial layer 112 and be in contact with the first oxide layer 212. At least a portion of the first oxide layer 212 may be located between the first polysilicon structure 211 and the first doped region 31. The first doped region 31 may be positioned between the first oxide layer 212 and the second surface 11B. In some embodiments, the first doped region 31 may be positioned between the bottom of the first trench structure 21 and the second surface 11B. From a top view, the first doped region 31 may be located below the first polysilicon structure 211 and at least partially overlaps with it. The wider the width W31 of the first doped region 31, the stronger the electric field intensity it can withstand under reverse voltage, thereby enhancing the voltage tolerance of the semiconductor structure 10. However, under forward voltage, this may cause the conductive channel to narrow, increasing resistance. Therefore, the concentration, width, and depth of the first doped region 31 can be adjusted as needed. In some embodiments, the width W31 of the first doped region 31 may be less than or equal to the width W211 of the first polysilicon structure 211. In some other embodiments, the width W31 of the first doped region 31 may be greater than the width W211 of the first polysilicon structure 211. In some other embodiments, the central axis of the first polysilicon structure 211 aligns vertically with the central axis of the first doped region 31.

The first doped region 31 has a conductivity type different from that of the epitaxial layer 112. The doping concentration of the first doped region 31 is higher than that of the epitaxial layer 112. At least a portion of the epitaxial layer 112 may be located between the first doped region 31 and the base material 111. In some embodiments, the first doped region 31 may have a second type of conductivity. For instance, in some embodiments, the first doped region 31 is of P-type, while the epitaxial layer 112 is of N-type. The first doped region 31 may contain P-type dopants, which may include elements such as boron, aluminum, gallium, or indium. In some embodiments, the P-type dopant in the first doped region 31 may be boron.

The first doped region 31 can reduce the electrical stress at the bottom of the first trench structure 21. The first doped region 31 has a first lower boundary 31p, the first oxide layer 212 has a second lower boundary 212p, and the first polysilicon structure 211 has a third lower boundary 211p. The first lower boundary 31p, the second lower boundary 212p, and the third lower boundary 211p are configured to withstand a reverse voltage of the semiconductor structure 10. In some embodiments, the horizontal level of the third lower boundary 211p may be higher than that of the second lower boundary 212p, and the horizontal level of the second lower boundary 212p may be higher than that of the first lower boundary 31p. When powered, the electric field at the first lower boundary 31p is greater than the electric field at the second lower boundary 212p, and the electric field at the second lower boundary 212p is greater than the electric field at the third lower boundary 211p. In some embodiments, the first doped region 31 may be in contact with the second lower boundary 212p.

The second trench structure 22 may be spaced apart from the first trench structure 21. The second trench structure 22 extends from the first surface 11A toward the second surface 11B, wherein the second trench structure 22 comprises a second polysilicon structure 221, as well as a second oxide layer 222 surrounding the second polysilicon structure 221. In some embodiments, the top surface of the second trench structure 22 may be coplanar with the first surface 11A. In some embodiments, the top surfaces of the second polysilicon structure 221 and the second oxide layer 222 may be coplanar with the first surface 11A. From a top view, the second trench structure 22 extends in the first direction X, parallel to the first surface 11A.

The second oxide layer 222 is used to electrically isolate the second polysilicon structure 221 from the epitaxial layer 112. In other words, the second polysilicon structure 221 is separated from the epitaxial layer 112 via the second oxide layer 222 within the trench. The second oxide layer 222 surrounds the second polysilicon structure 221. The sidewalls and bottom wall of the second polysilicon structure 221 are in contact with the second oxide layer 222. The second oxide layer 222 includes a bottom wall portion 222a and a sidewall portion 222b, which is positioned above the bottom wall portion 222a and surrounds the sidewalls of the second polysilicon structure 221. The second polysilicon structure 221 is located on the bottom wall portion 222a of the second oxide layer 222, and its sidewalls are surrounded by the sidewall portion 222b of the second oxide layer 222. In some embodiments, the second polysilicon structure 221 may be a columnar structure.

The thickness T3 of the bottom wall portion 222a and the thickness T4 of the sidewall portion 222b of the second oxide layer 222 can be adjusted based on the size of the second polysilicon structure 221 or the operating voltage. For example, the thickness T4 of the sidewall portion 222b of the second oxide layer 222 may be less than or equal to the width W221 of the second polysilicon structure 221 within the trench. The second oxide layer 222 may contain silicon oxide. In some embodiments, the second polysilicon structure 221 may contain polysilicon material. In some embodiments, the electrical stress of the second oxide layer 222 can be reduced by adjusting the thickness T3 of the bottom wall portion 222a of the second oxide layer 222, such as by making the thickness T3 of the bottom wall portion 222a greater than the thickness T4 of the sidewall portion 222b. In some other embodiments, the thickness T1 is substantially equal to the thickness T3. In some other embodiments, the thickness T2 is substantially equal to the thickness T4.

The substrate 11 may comprise a second doped region 32, which extends in the first direction X. In some embodiments, the second doped region 32 may be positioned between the first surface 11A and the second surface 11B, adjacent to the second oxide layer 222 and separated from the second polysilicon structure 221. In some embodiments, the second doped region 32 may be located within the epitaxial layer 112 and be in contact with the second oxide layer 222. At least a portion of the second oxide layer 222 may be located between the second polysilicon structure 221 and the second doped region 32. The second doped region 32 may be positioned between the second oxide layer 222 and the second surface 11B. In some embodiments, the second doped region 32 may be positioned between the bottom of the second trench structure 22 and the second surface 11B. From a top view, the second doped region 32 may be located below the second polysilicon structure 221 and at least partially overlaps with it.

The distance between the second doped region 32 and the first surface 11A may be the same as or different from the distance between the first doped region 31 and the first surface 11A. In some embodiments, the distance between the second doped region 32 and the first surface 11A may be substantially the same as the distance between the first doped region 31 and the first surface 11A. The wider the width W32 of the second doped region 32, the stronger the electric field intensity it can withstand under reverse voltage, thereby enhancing the voltage tolerance of the semiconductor structure 10. However, under forward voltage, this may cause the conductive channel to narrow, increasing resistance. Therefore, the concentration, width, and depth of the second doped region 32 can be adjusted as needed. In some embodiments, the width W32 of the second doped region 32 may be less than or equal to the width W221 of the second polysilicon structure 221. In some other embodiments, the width W32 of the second doped region 32 may be greater than the width W221 of the second polysilicon structure 221. In some other embodiments, the central axis of the second polysilicon structure 221 aligns vertically with the central axis of the second doped region 32.

The second doped region 32 has a conductivity type different from that of the epitaxial layer 112, and its doping concentration is higher than that of the epitaxial layer 112. At least a portion of the epitaxial layer 112 may be located between the second doped region 32 and the base material 111. In some embodiments, the second doped region 32 may have a second conductivity type. For instance, in some embodiments, the second doped region 32 may be of P-type, while the epitaxial layer 112 may be of N-type. The second doped region 32 may contain P-type dopants, which may include elements such as boron, aluminum, gallium, or indium. In some embodiments, the P-type dopant in the second doped region 32 may be boron.

The second doped region 32 can reduce electrical stress at the bottom of the second trench structure 22. The second doped region 32 has a sixth lower boundary 32p, the first oxide layer 212 has a seventh lower boundary 222p, and the first polysilicon structure 211 has an eighth lower boundary 221p. The sixth lower boundary 32p, seventh lower boundary 222p, and eighth lower boundary 221p are configured to withstand the reverse voltage of the semiconductor structure 10. In some embodiments, the horizontal level of the eighth lower boundary 221p may be higher than that of the seventh lower boundary 222p, and the horizontal level of the seventh lower boundary 222p may be higher than that of the sixth lower boundary 32p. When powered, the electric field at the sixth lower boundary 32p is greater than the electric field at the seventh lower boundary 222p, and the electric field at the seventh lower boundary 222p is greater than the electric field at the eighth lower boundary 221p. The closer the horizontal level of the lower boundary is to the second surface 11B, the greater the electric field. In some embodiments, the second doped region 32 may be in contact with the seventh lower boundary 222p.

The substrate 11 between the first trench structure 21 and the second trench structure 22 forms a mesa surface. In some embodiments, the mesa separates the first trench structure 21 from the second trench structure 22. The width of the mesa surface can be adjusted based on the positions of the first trench structure 21 and the second trench structure 22.

In some embodiments, the substrate 11 may further comprise a third doped region 33 located between the first trench structure 21 and the second trench structure 22. The third doped region 33 may be positioned on the mesa, for example, near the center of the mesa and adjacent to the first surface 11A, to reduce the electric field on the mesa and minimize leakage current. In some other embodiments, the third doped region 33 is positioned centrally between the first trench structure 21 and the second trench structure 22. The width of the third doped region 33 may be smaller than the width of the mesa; in other words, the third doped region 33 may be surrounded by the epitaxial layer 112. The third doped region 33 extends from the first surface 11A to the second surface 11B. In some embodiments, the distance between the first doped region 31 and the first surface 11A may be greater than the distance between the third doped region 33 and the first surface 11A. In some embodiments, the distance between the second doped region 32 and the first surface 11A may be greater than the distance between the third doped region 33 and the first surface 11A.

The third doped region 33 has a conductivity type different from that of the epitaxial layer 112, and its doping concentration is higher than that of the epitaxial layer 112. In some embodiments, the third doped region 33 may have a second type of conductivity. For example, in some embodiments, the third doped region 33 is of P-type, while the epitaxial layer 112 is of N-type. The third doped region 33 may contain P-type dopants, which may include elements such as boron, aluminum, gallium, or indium. In some embodiments, the P-type dopant in the third doped region 33 may be boron.

The shielding metal layer 35 is located on the first surface 11A of the substrate 11, covering the first trench structure 21, the second trench structure 22, and the third doped region 33. The shielding metal layer 35 is in contact with the first polysilicon structure 211, the second polysilicon structure 221, and the third doped region 33. The shielding metal layer 35 may include nickel (Ni), titanium (Ti), molybdenum (Mo), or other metals or alloys.

The first conductive layer 36 is disposed on the shielding metal layer 35. The first conductive layer 36 is in contact with and electrically connected to the shielding metal layer 35. The first conductive layer 36 contains a conductive material, such as a metal, which may include, but is not limited to, copper (Cu), gold (Au), silver (Ag), aluminum (Al), nickel (Ni), titanium (Ti), tungsten (W), tin (Sn), titanium nitride (TiN), aluminum-silicon (AlSi) alloy, aluminum-silicon-copper (AlSiCu) alloy, or other metals or alloys. In some embodiments, the thickness of the first conductive layer 36 may be greater than the thickness of the shielding metal layer 35.

The second conductive layer 37 is disposed on the second surface 11B of the substrate 11 and is in contact with the base material 111. The second conductive layer 37 contains a conductive material, such as a metal, which may include, but is not limited to, copper, gold, silver, aluminum, nickel, titanium, tungsten, tin, titanium nitride, aluminum-silicon alloy, aluminum-silicon-copper alloy, or other metals or alloys. The first conductive layer 36 and the second conductive layer 37 may contain the same conductive material or different conductive materials. In some embodiments, the thickness of the first conductive layer 36 may be greater than the thickness of the second conductive layer 37.

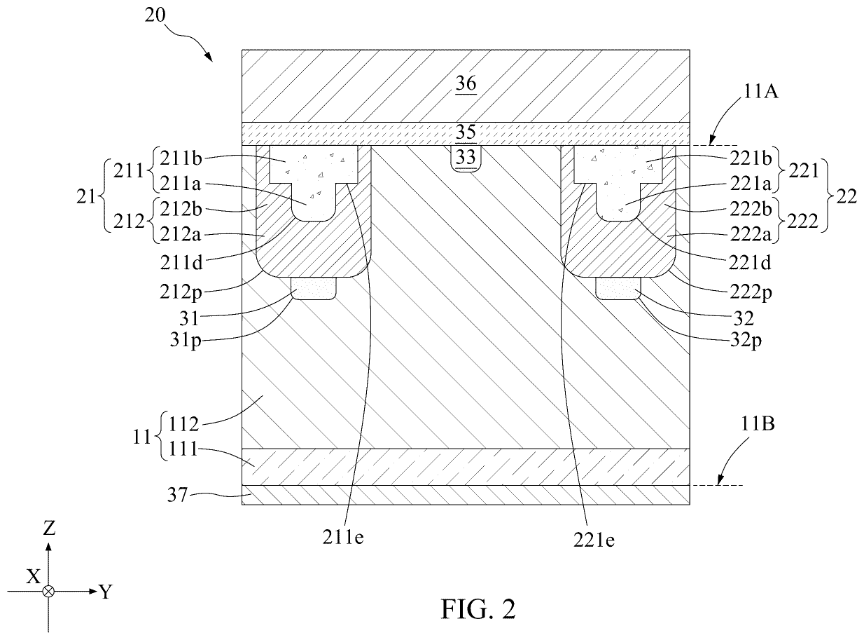

FIG. 2 shows a cross-sectional view of an example of a semiconductor structure 20 in accordance with various embodiments of the present disclosure. Specifically, the semiconductor structure 20 is a trench-type MOS rectifier device structure with a vertical current conduction path. For example, current in the semiconductor structure 20 can conduct vertically through the structure. As shown in FIG. 2, the semiconductor structure 20 is similar to the semiconductor structure 10 shown in FIG. 1, with the difference being in the shapes of the first polysilicon structure 211 and the second polysilicon structure 221.

In some embodiments, the first polysilicon structure 211 may have a stepped structure. In some embodiments, the first polysilicon structure 211 may be a stepped structure that is wider at the top and narrower at the bottom, with the width of the first polysilicon structure 211 decreasing along the vertical direction Z from the first surface 11A toward the second surface 11B. In some embodiments, the first polysilicon structure 211 may comprise a first portion 211a and a second portion 211b connected to the first portion 211a. The width of the second portion 211b may be greater than that of the first portion 211a, forming a stepped structure between the two. The first portion 211a and second portion 211b of the first polysilicon structure 211 are surrounded by the sidewall portion 212b of the first oxide layer 212. In some embodiments, by adjusting the shape or structure of the sidewall portion 212b of the first oxide layer 212, the electric field distribution in the epitaxial layer 112 can be modified, allowing the semiconductor structure 10 to achieve a higher breakdown voltage, or to achieve a similar breakdown voltage with a lower epitaxial concentration.

The structure of the sidewall portion 212b of the first oxide layer 212 can be adjusted based on the structure of the first polysilicon structure 211 or the operating voltage. For example, the sidewall portion 212b of the first oxide layer 212 may also have a stepped structure. In some embodiments, corresponding to the stepped structure of the first polysilicon structure 211 that is wider at the top and narrower at the bottom, the sidewall portion 212b of the first oxide layer 212 may be configured in a stepped form that is narrower at the top and wider at the bottom, with the width of the sidewall portion 212b of the first oxide layer 212 increasing along the vertical direction Z from the first surface 11A toward the second surface 11B.

In some embodiments, the first doped region 31 has a first lower boundary 31p, the first oxide layer 212 has a second lower boundary 212p, the first portion 211a of the first polysilicon structure 211 has a fourth lower boundary 211d, and the second portion 211b of the first polysilicon structure 211 has a fifth lower boundary 211e. The first lower boundary 31p, the second lower boundary 212p, the fourth lower boundary 211d, and the fifth lower boundary 211e are configured to withstand a reverse voltage of the semiconductor structure 20. The horizontal level of the fifth lower boundary 211e may be higher than that of the fourth lower boundary 211d, the horizontal level of the fourth lower boundary 211d may be higher than that of the second lower boundary 212p, and the horizontal level of the second lower boundary 212p may be higher than that of the first lower boundary 31p.

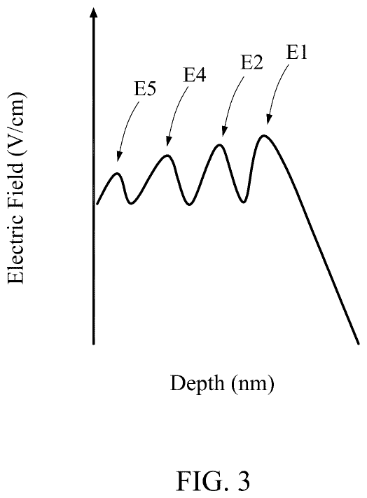

FIG. 3 shows a graph illustrating the relationship between depth and electric field of the semiconductor structure 20 according to certain embodiments of the present disclosure. As shown in FIG. 2 and FIG. 3, in some embodiments, the depth of the first lower boundary 31p may be greater than that of the second lower boundary 212p, the depth of the second lower boundary 212p may be greater than that of the fourth lower boundary 211d, and the depth of the fourth lower boundary 211d may be greater than that of the fifth lower boundary 211e. When powered, the peak electric field E1 at the first lower boundary 31p is greater than the peak electric field E2 at the second lower boundary 212p, the peak electric field E2 at the second lower boundary 212p is greater than the peak electric field E4 at the fourth lower boundary 211d, and the peak electric field E4 at the fourth lower boundary 211d is greater than the peak electric field E5 at the fifth lower boundary 211e. In summary, the deeper the lower boundary is located in the epitaxial layer 112 relative to the first surface 11A, the higher the electric field. Through the configuration and structure of the first polysilicon structure 211, the first oxide layer 212, and the first doped region 31, the semiconductor structure 20 achieves a high breakdown voltage.

Referring to FIG. 2, in some embodiments, the second polysilicon structure 221 may have a stepped structure. In some embodiments, the second polysilicon structure 221 may be a stepped structure that is wider at the top and narrower at the bottom, with the width of the second polysilicon structure 221 decreasing along the vertical direction Z from the first surface 11A to the second surface 11B. In some embodiments, the second polysilicon structure 221 may include a first portion 221a and a second portion 221b connected to the first portion 221a. The width of the second portion 221b may be greater than that of the first portion 221a, forming a stepped structure between the two. The first portion 221a and the second portion 221b of the second polysilicon structure 221 are surrounded by the sidewall portion 222b of the second oxide layer 222.

The structure of the sidewall portion 222b of the second oxide layer 222 can be adjusted based on the structure of the second polysilicon structure 221 or the operating voltage; for example, the sidewall portion 222b of the second oxide layer 222 may also have a stepped structure. In some embodiments, corresponding to the stepped structure of the second polysilicon structure 221 that is wider at the top and narrower at the bottom, the sidewall portion 222b of the second oxide layer 222 may be configured in a stepped form that is narrower at the top and wider at the bottom, with the width of the sidewall portion 222b of the second oxide layer 222 increasing along the vertical direction Z from the first surface 11A to the second surface 11B. The electric field distribution in the epitaxial layer 112 can be adjusted by modifying the shape or structure of the sidewall portion 222b of the second oxide layer 222, allowing the semiconductor structure 20 to achieve a higher breakdown voltage or to reach a similar breakdown voltage with a lower epitaxial concentration.

In some embodiments, the second doped region 32 has a sixth lower boundary 32p, the second oxide layer 222 has a seventh lower boundary 222p, the first portion 221a of the second polysilicon structure 221 has a ninth lower boundary 221d, and the second portion 221b of the second polysilicon structure 221 has a tenth lower boundary 221e. The sixth lower boundary 32p, the seventh lower boundary 222p, the ninth lower boundary 221d, and the tenth lower boundary 221e are configured to withstand the reverse voltage of the semiconductor structure 20. The horizontal level of the tenth lower boundary 221e may be higher than that of the ninth lower boundary 221d, the horizontal level of the ninth lower boundary 221d may be higher than that of the seventh lower boundary 222p, and the horizontal level of the seventh lower boundary 222p may be higher than that of the sixth lower boundary 32p.

In some embodiments, the depth of the sixth lower boundary 32p may be greater than that of the seventh lower boundary 222p, the depth of the seventh lower boundary 222p may be greater than that of the ninth lower boundary 221d, and the depth of the ninth lower boundary 221d may be greater than that of the tenth lower boundary 221e. When powered, the electric field at the sixth lower boundary 32p is greater than the electric field at the seventh lower boundary 222p, the electric field at the seventh lower boundary 222p is greater than the electric field at the ninth lower boundary 221d, and the electric field at the ninth lower boundary 221d is greater than the electric field at the tenth lower boundary 221e. The relationships among the sixth lower boundary 32p, the seventh lower boundary 222p, the ninth lower boundary 221d, and the tenth lower boundary 221e concerning the electric field are analogous to the depth-to-electric field relationship illustrated in FIG. 3. Specifically, the deeper the lower boundary is situated within the epitaxial layer 112 relative to the first surface 11A, the greater the electric field strength.

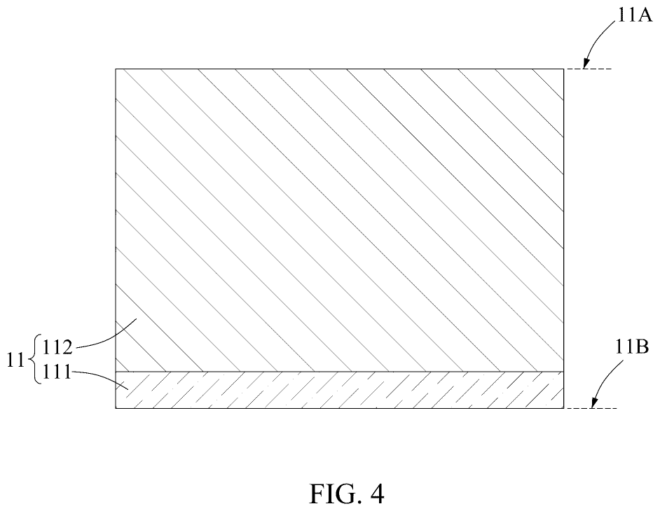

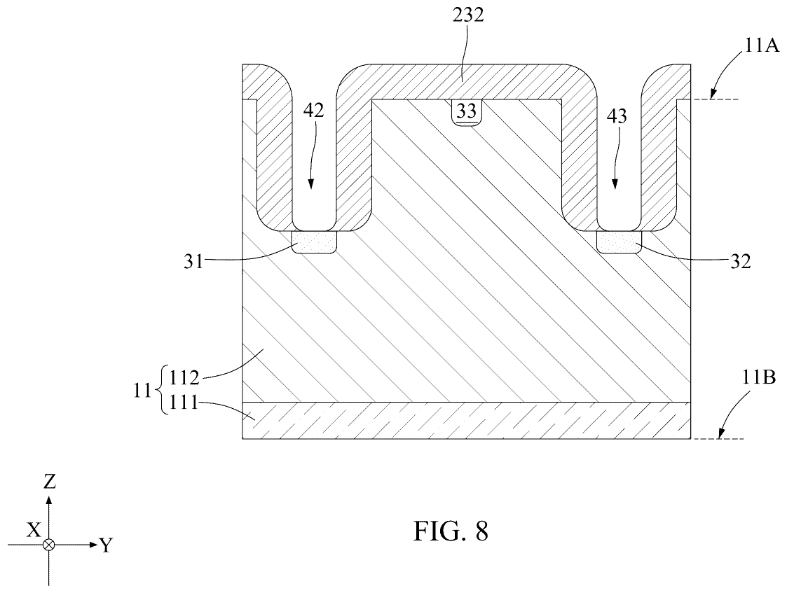

FIGS. 4 to 19 illustrate one or more stages in the manufacturing method of the semiconductor structure according to various embodiments of the present disclosure. Some of the illustrations in these figures have been simplified to enhance the understanding of the disclosed embodiment.

Referring to FIG. 4, the substrate 11 may comprise a base material 111 and an epitaxial layer 112 situated on the base material 111. The manufacturing method comprises the epitaxial growth of the base material 111 to form the epitaxial layer 112. The epitaxial layer 112 has a first surface 11A of the substrate 11, while the base material 111 has a second surface 11B of the substrate 11, with the first surface 11A and the second surface 11B being opposite each other. In some embodiments, the epitaxial growth may be performed simultaneously with ion implantation, injecting ions with N-type electrical properties to form the N-type epitaxial layer 112.

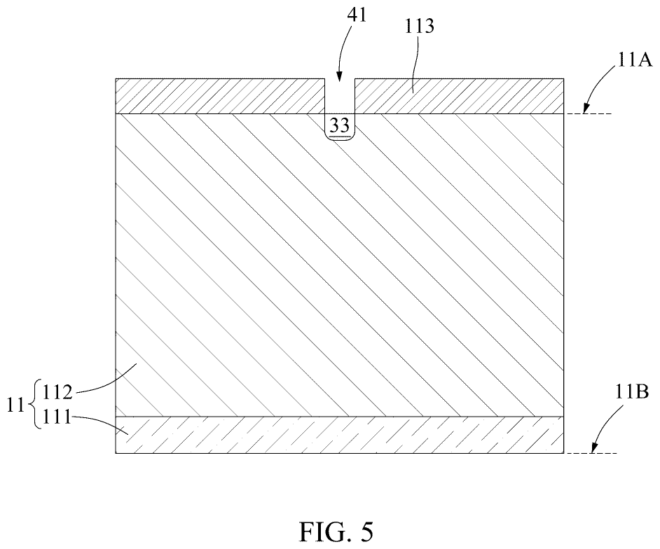

Referring to FIG. 5, a first patterned shielding layer 113 may be formed on the epitaxial layer 112 to define the position of the third doped region 33. The first patterned shielding layer 113 has a first opening 41, and the manufacturing method further comprises forming the third doped region 33 on the first surface 11A exposed by the first opening 41. The third doped region 33 can be formed via diffusion or ion implantation processes from the first surface 11A. In some embodiments, the third doped region 33 extends in the first direction X. After the ion implantation process, an annealing process is performed to allow the doped ions to diffuse. The doped ions may include boron ions, aluminum ions, gallium ions, indium ions, and so on. In some embodiments, boron ions may be implanted into the third doped region 33, and after forming the third doped region 33, the first patterned shielding layer 113 is removed.

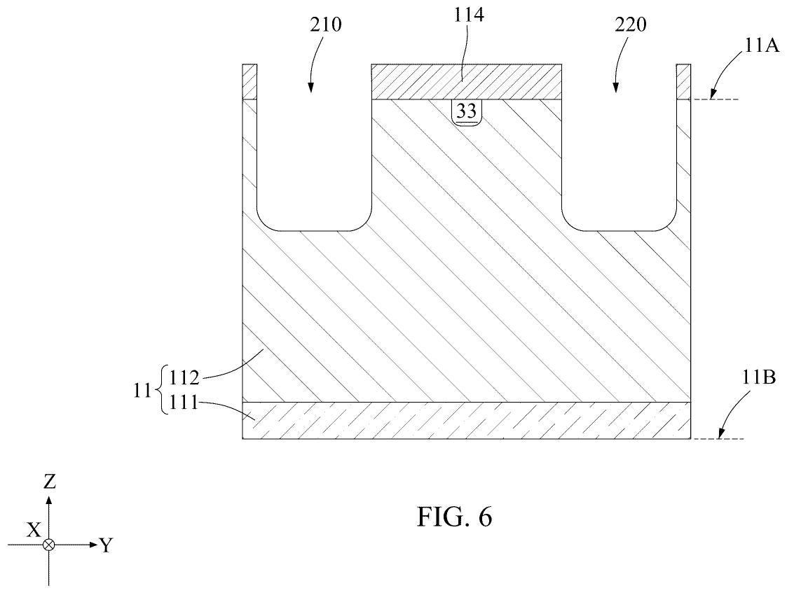

Referring to FIG. 6, a second patterned shielding layer 114 may be formed on the epitaxial layer 112 and the third doped region 33 to define the positions of a first trench 210 and a second trench 220. An etching process (e.g., plasma etching) is performed on the epitaxial layer 112 through the second patterned shielding layer 114 to form the first trench 210 and the second trench 220. The third doped region 33 may be located between the first trench 210 and the second trench 220. The etching process removes material from the epitaxial layer 112 starting from the first surface 11A and stops within the epitaxial layer 112. Based on the position of the second patterned shielding layer 114, the first trench 210 and the second trench 220 are formed in the substrate 11, spaced apart and extending along the first direction X from the first surface 11A to the second surface 11B. After forming the first trench 210 and the second trench 220, the second patterned shielding layer 114 is removed.

In some embodiments, the first trench 210 and the second trench 220 may have vertical sidewalls. The first trench 210 and the second trench 220 may also have an arcuate bottom surface. Additionally, in some embodiments, the first trench 210 and the second trench 220 may be circular, elliptical, rectangular, or polygonal in shape. In some embodiments, the first trench 210 and the second trench 220 may have the same width. In some embodiments, the first trench 210 and the second trench 220 may have the same depth.

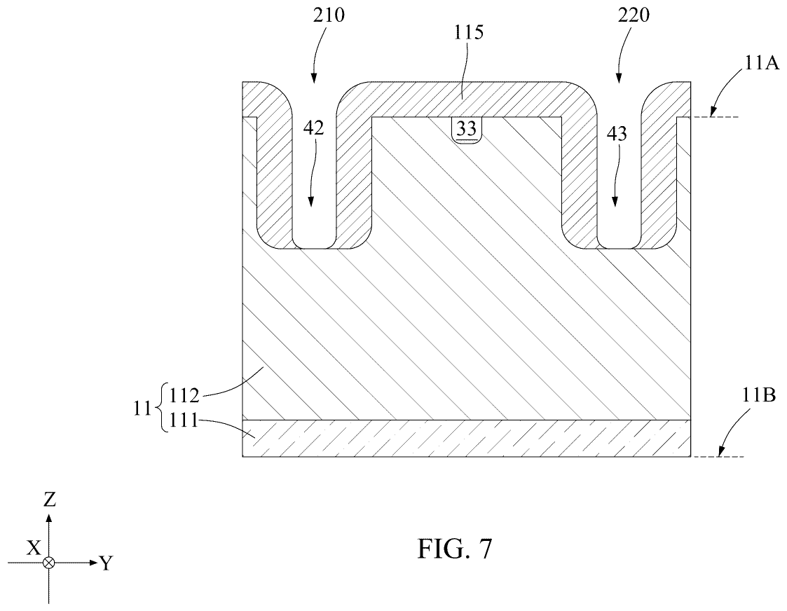

Referring to FIGS. 7, 8, and 9, the manufacturing method may further comprise forming a third patterned shielding layer 115 on the epitaxial layer 112 and the third doped region 33, as well as within the first trench 210 and the second trench 220, to define the positions of the first doped region 31 and the second doped region 32. The third patterned shielding layer 115 has a second opening 42 and a third opening 43. The second opening 42 is formed in the first trench 210 to expose a portion of the epitaxial layer 112, and the third opening 43 is formed in the second trench 220 to expose a portion of the epitaxial layer 112. The manufacturing method may further comprise forming the first doped region 31 in the substrate 11, with the first doped region 31 adjacent to the bottom of the first trench 210, and forming the second doped region 32 in the substrate 11, with the second doped region 32 adjacent to the bottom of the second trench 220.

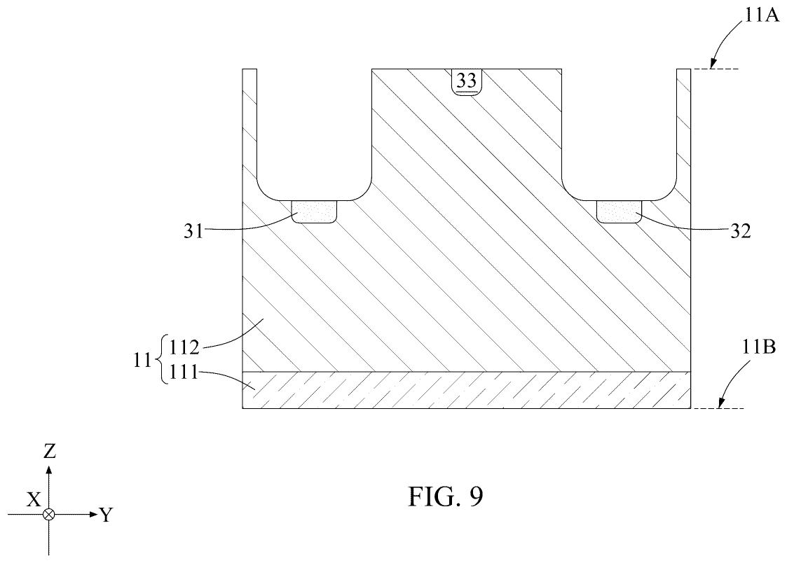

The first doped region 31 may be formed through diffusion or ion implantation processes from the second opening 42. The second doped region 32 may be formed through diffusion or ion implantation processes from the third opening 43. The first doped region 31 and the second doped region 32 may be formed simultaneously. The first doped region 31 and the second doped region 32 extend in the first direction X. After the ion implantation process, an annealing process is conducted to allow the doped ions to diffuse. In some embodiments, the doped ions may include boron ions, aluminum ions, gallium ions, indium ions, and others. In some embodiments, boron ions are implanted into both the first doped region 31 and the second doped region 32. In some embodiments, a third doped region 33 may be formed prior to forming the first doped region 31 and the second doped region 32. As shown in FIG. 9, after forming the first doped region 31 and the second doped region 32, the third patterned shielding layer 115 is removed.

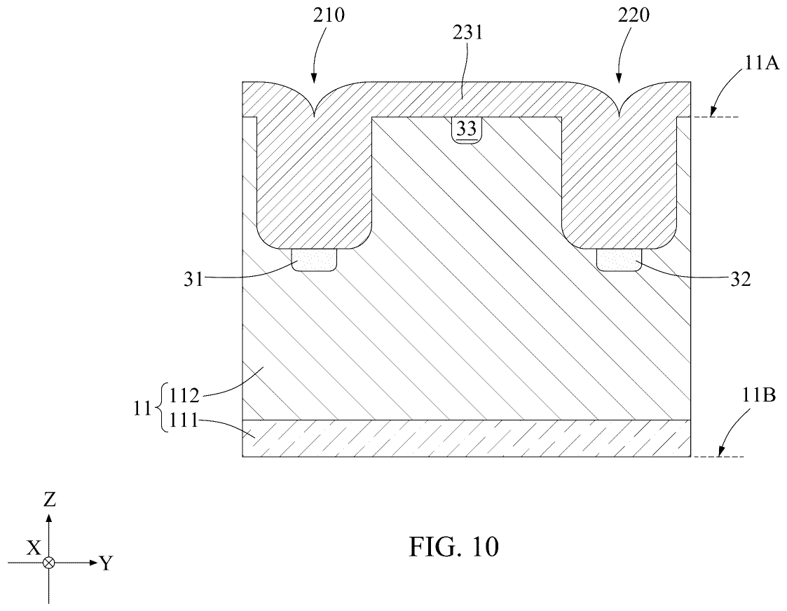

Referring to FIG. 10, the manufacturing method may further comprise forming a first trench oxide layer 231 in the first trench 210 and the second trench 220. The first trench oxide layer 231 covers the first surface 11A. The first trench oxide layer 231 may be formed through thermal oxidation techniques or other deposition processes. The first trench oxide layer 231 can be deposited either conformally or with step coverage on the inner surfaces of the first trench 210 and the second trench 220 (including the opposing sidewalls and the bottom extending between the sidewalls). In some embodiments, the first trench oxide layer 231 may be deposited to fill the first trench 210 and the second trench 220 through deposition processes, ensuring coverage of the first doped region 31 in the first trench 210 and the second doped region 32 in the second trench 220. In some embodiments, the first trench oxide layer 231 may be deposited to fill the first trench 210 and the second trench 220 until the indentation along the top curved surface of the first trench oxide layer 231 reaches a height that is level with or above the first surface 11A. In some embodiments, the first trench oxide layer 231 may comprise silicon oxide.

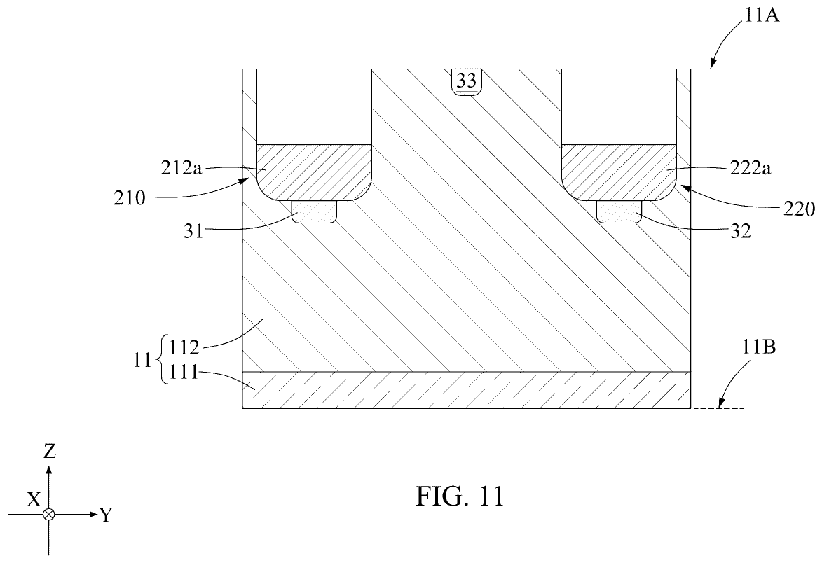

Referring to FIG. 11, the first trench oxide layer 231 outside the first trench 210 and the second trench 220, as well as a portion of the first trench oxide layer 231 within the first trench 210 and the second trench 220, may be removed using methods such as dry etching or other etching techniques. This forms the bottom wall portion 212a located within the first trench 210 and the bottom wall portion 222a located within the second trench 220. The etching process, such as dry etching, will stop at a predetermined depth within the first trench 210 and the second trench 220. In some embodiments, the bottom wall portion 212a and the bottom wall portion 222a may be formed simultaneously.

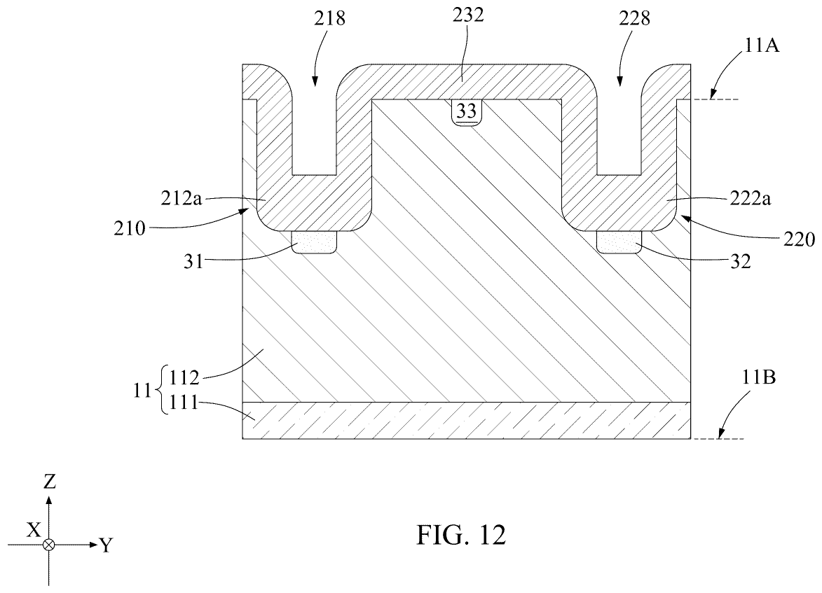

Referring to FIG. 12, the manufacturing method may further comprise forming a second trench oxide layer 232 in the first trench 210 and the second trench 220. The second trench oxide layer 232 covers the first surface 11A and is located on the bottom wall portions 212a and 222a. The second trench oxide layer 232 may be deposited in a conformal or step coverage manner on the inner surfaces of the first trench 210 and the second trench 220, as well as on the bottom wall portions 212a and 222a. In some embodiments, the second trench oxide layer 232 may be formed through thermal oxidation techniques or other deposition processes. In some embodiments, the second trench oxide layer 232 may be deposited to fill the first trench 210 and the second trench 220 through deposition processes, creating a recess 218 in the first trench 210 and a recess 228 in the second trench 220. In some embodiments, the second trench oxide layer 232 may comprise silicon oxide.

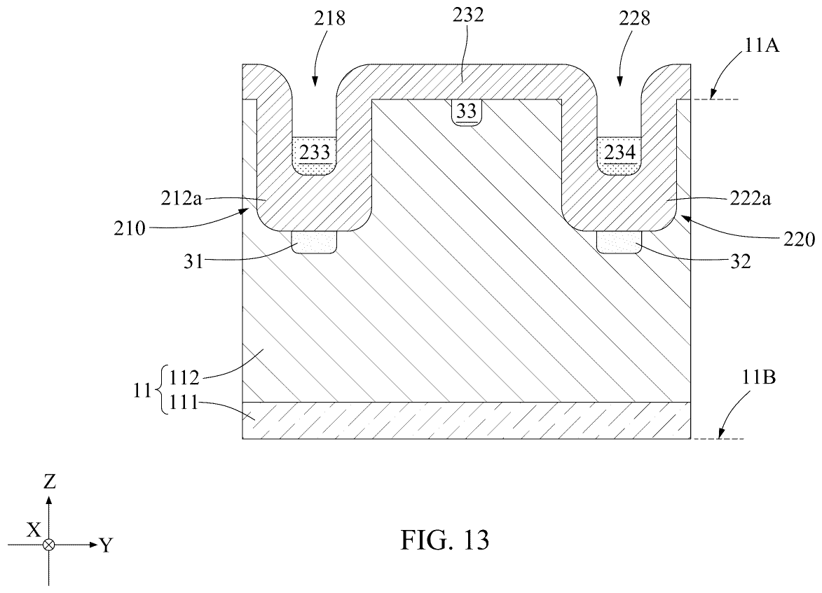

Referring to FIG. 13, the manufacturing method may further comprise forming a first protective layer 233 in the recess 218 and a second protective layer 234 in the recess 228. The first protective layer 233 is formed on the bottom wall portion 212a, while the second protective layer 234 is formed on the bottom wall portion 222a. The first protective layer 233 and the second protective layer 234 may have different etching selectivities compared to the second trench oxide layer 232. The first protective layer 233 and the second protective layer 234 can be deposited to fill the recesses 218 and 228, respectively, through deposition processes. In some embodiments, the first protective layer 233 and the second protective layer 234 may be formed simultaneously.

In some embodiments, the first protective layer 233 and the second protective layer 234 may comprise silicon nitride. The first protective layer 233 may be deposited conformally or with step coverage on a portion of the inner surface of the recess 218, while part of the inner surface of the recess 218 remains uncovered by the first protective layer 233. In some embodiments, the first protective layer 233 may contact portions of the sidewalls of the recess 218 and the bottom extending between the sidewalls, with parts of the sidewalls of the recess 218 exposed beyond the first protective layer 233. The second protective layer 234 may also be deposited conformally or with step coverage on a portion of the inner surface of the recess 228, while part of the inner surface of the recess 228 remains uncovered by the second protective layer 234. In some embodiments, the second protective layer 234 may contact portions of the sidewalls of the recess 228 and the bottom extending between the sidewalls, with parts of the sidewalls of the recess 228 exposed beyond the second protective layer 234.

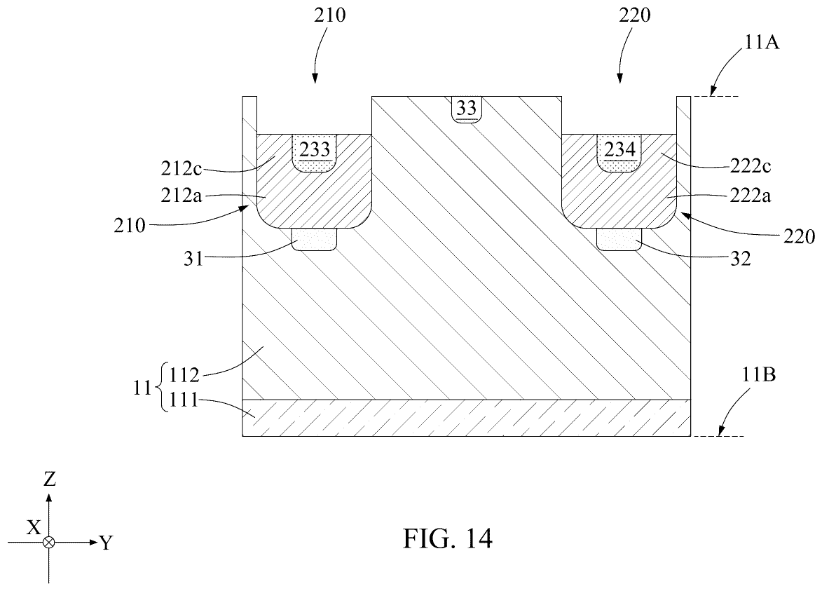

Referring to FIG. 14, the manufacturing method may further comprise removing the second trench oxide layer 232 that does not contact the first protective layer 233 or the second protective layer 234. The portion of the second trench oxide layer 232 may be removed using methods such as etching, forming the first sidewall 212c in the first trench 210 and the second sidewall 222c in the second trench 220. In some embodiments, the top surface of first sidewall 212c may be coplanar with the top surface of the first protective layer 233, while the top surface of second sidewall 222c may be coplanar with the top surface of the second protective layer 234. In some embodiments, the first sidewall 212c and the second sidewall 222c may be formed simultaneously.

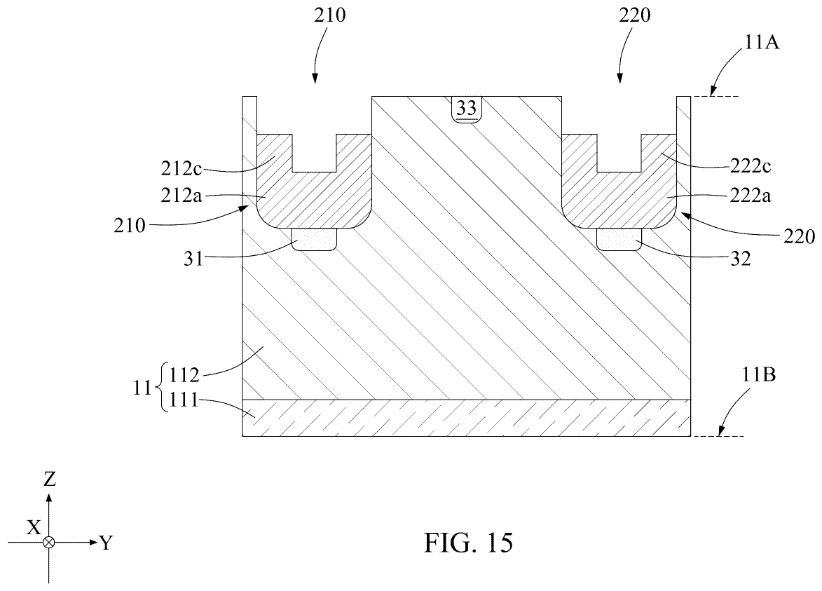

Referring to FIG. 15, the manufacturing method may further comprise removing the first protective layer 233 and the second protective layer 234. The first protective layer 233 and the second protective layer 234 are removed after forming the first sidewall 212c and the second sidewall 222c, exposing portions of the bottom wall portions 212a and 222a.

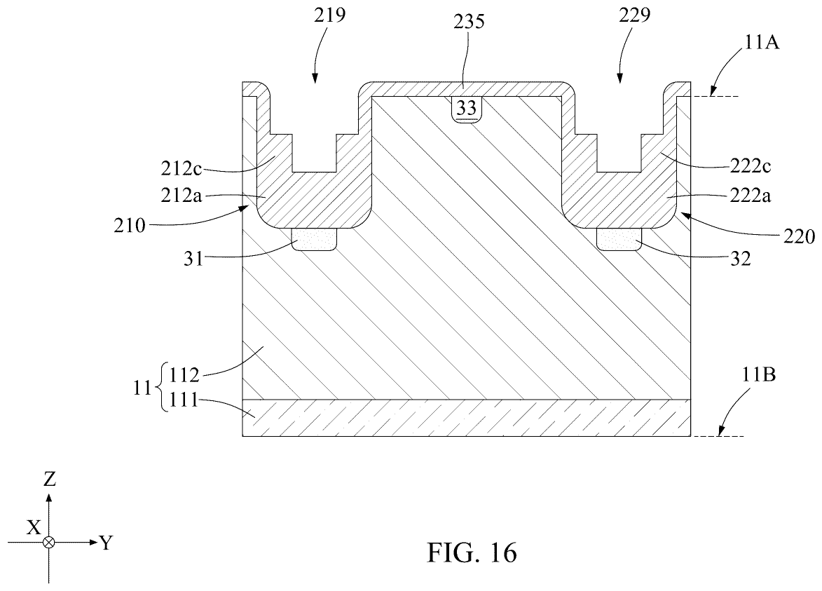

Referring to FIG. 16, the manufacturing method may further comprise forming a third trench oxide layer 235 in the first trench 210 and the second trench 220. The third trench oxide layer 235 covers the first surface 11A and is positioned on the first sidewall 212c and the second sidewall 222c. The third trench oxide layer 235 may be formed through thermal oxidation techniques or other deposition processes. In some embodiments, the third trench oxide layer 235 may be deposited conformally or with step coverage on the inner surfaces of the first trench 210 and the second trench 220, making contact with the top surfaces of the first sidewall 212c and the second sidewall 222c. In some embodiments, the third trench oxide layer 235 may be deposited to fill the first trench 210 and the second trench 220 through deposition processes, creating a space 219 in the first trench 210 and a space 229 in the second trench 220. In some embodiments, the third trench oxide layer 235 may comprise silicon oxide.

In some embodiments, the thickness of the third trench oxide layer 235 may be less than the thickness of the first sidewall 212c and the thickness of the second sidewall 222c. The spaces 219 and 229 may have stepped sidewalls.

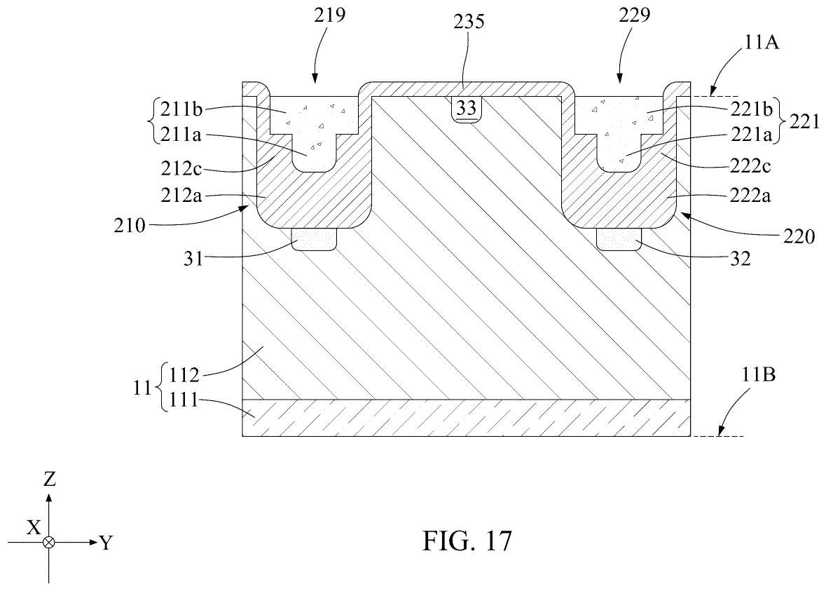

Referring to FIG. 17, the manufacturing method may further comprise forming a first polysilicon structure 211 in the first trench 210 and forming a second polysilicon structure 221 in the second trench 220. The manufacturing method may further comprise forming the first polysilicon structure 211 in the space 219 and the second polysilicon structure 221 in the space 229. In some embodiments, in the first trench 210, the first polysilicon structure 211 is formed on the bottom wall portion 212a and is surrounded by the first sidewall 212c and the third trench oxide layer 235. In some embodiments, in the second trench 220, the second polysilicon structure 221 is formed on the bottom wall portion 222a and is surrounded by the second sidewall 222c and the third trench oxide layer 235.

The first polysilicon structure 211 and the second polysilicon structure 221 may be formed through physical vapor deposition (PVD), such as sputtering or spraying. They can also be formed through electroplating or chemical vapor deposition (CVD). The polysilicon material can cover the third trench oxide layer 235, and then a dry etching process may be performed to remove the polysilicon material outside the first trench 210 and the second trench 220 using methods such as etching, thereby forming the first polysilicon structure 211 and the second polysilicon structure 221.

The shapes of the first polysilicon structure 211 and the second polysilicon structure 221 correspond to the shapes of the spaces 219 and 229, respectively. In some embodiments, spaces 219 and 229 may have stepped sidewalls, and the first polysilicon structure 211 and the second polysilicon structure 221 also may have a stepped structure.

In some embodiments, the first polysilicon structure 211 may comprise a first portion 211a and a second portion 211b connected to the first portion 211a, where the width of the second portion 211b may be greater than that of the first portion 211a, and the two portions 211a and 211b may be formed integrally. In some embodiments, the second polysilicon structure 221 may comprise a first portion 221a and a second portion 221b connected to the first portion 221a, where the width of the second portion 221b may be greater than that of the first portion 221a, and the two portions 221a and 221b may be formed integrally.

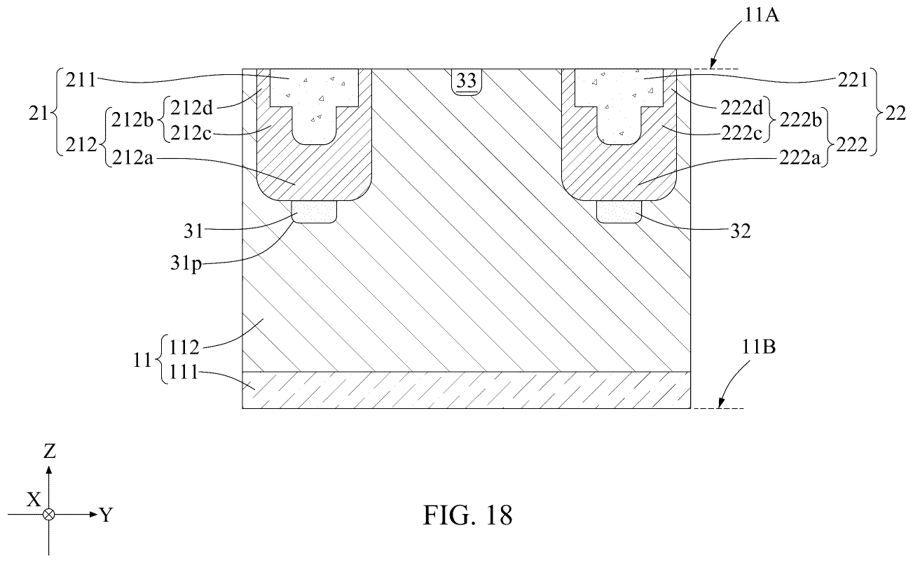

Referring to FIG. 18, the manufacturing method may further comprise removing the third trench oxide layer 235 outside the first trench 210 and the second trench 220 using methods such as etching, to form the first trench structure 21 and the second trench structure 22. The first trench structure 21 is formed in the first trench 210 and comprises the first oxide layer 212 and the first polysilicon structure 211, which is surrounded by the first oxide layer 212. The second trench structure 22 is formed in the second trench 220 and comprises the second oxide layer 222 and the second polysilicon structure 221, which is surrounded by the second oxide layer 222. In some embodiments, the first trench structure 21 and the second trench structure 22 are formed simultaneously. In some embodiments, the manufacturing method may further comprise aligning the top surfaces of the first trench structure 21 and the second trench structure 22 to be coplanar with the first surface 11A.

In some embodiments, the third trench oxide layer 235 outside the first trench 210 and the second trench 220 is removed to form the third sidewall 212d located in the first trench 210 and the fourth sidewall 222d located in the second trench 220. In some embodiments, the third sidewall 212d and the fourth sidewall 222d may be formed simultaneously. The top surface of the third sidewall 212d may be coplanar with the first surface 11A, and the top surface of the fourth sidewall 222d may also be coplanar with the first surface 11A. The first sidewall 212c and the third sidewall 212d together form the sidewall portion 212b of the first oxide layer 212. The sidewall portion 212b and the bottom wall portion 212a constitute the first oxide layer 212. The sidewall portion 212b of the first oxide layer 212 may have a stepped structure. The second sidewall 222c and the fourth sidewall 222d together form the sidewall portion 222b of the second oxide layer 222. The sidewall portion 222b and the bottom wall portion 222a constitute the second oxide layer 222. The sidewall portion 222b of the second oxide layer 222 may also have a stepped structure.

In some embodiments, to form the semiconductor structure 10 shown in FIG. 1, the manufacturing method may further comprise aligning the top surfaces of the formed sidewall portion 212b of the first oxide layer 212 and the formed sidewall portion 222b of the second oxide layer 222 to be coplanar with the first surface 11A, while omitting the steps shown in FIGS. 13 to 16 including formations of the first protective layer 233, the second protective layer 234, the third trench oxide layer 235, and the third sidewall 212d and fourth sidewall 222d. The first polysilicon structure 211 is formed in the recess 218, and the second polysilicon structure 221 is formed in the recess 228. In some embodiments, the first polysilicon structure 211 formed in the recess 218 may have a columnar structure, and the second polysilicon structure 221 formed in the recess 228 may also have a columnar structure. In some embodiments, the sidewalls of the first polysilicon structure 211 may align vertically with the sidewalls of the first doped region 31 in a cross-sectional view. In some embodiments, the sidewalls of the second polysilicon structure 221 may align vertically with the sidewalls of the second doped region 32 in a cross-sectional view. In some embodiments, after the first polysilicon structure 211 is formed in the recess 218 and the second polysilicon structure 221 is formed in the recess 228, the second trench oxide layer 232 outside the first trench 210 and the second trench 220 is removed to form the first trench structure 21 in the first trench 210 and the second trench structure 22 in the second trench 220.

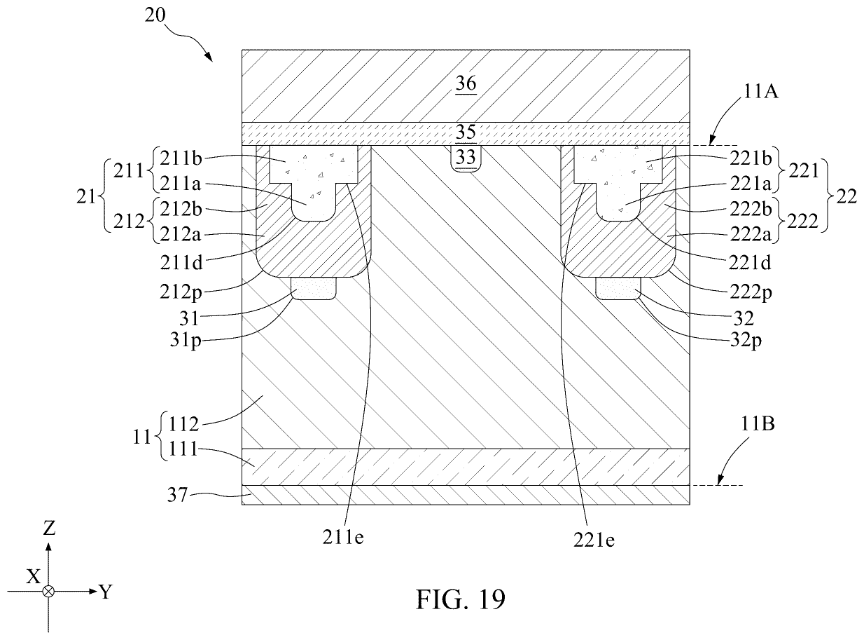

Referring to FIG. 19, the manufacturing method may further comprise forming a shielding metal layer 35 on the first trench structure 21, the second trench structure 22, and the first surface 11A, ensuring that the shielding metal layer 35 contacts both the first trench structure 21 and the second trench structure 22. The manufacturing method may further comprise forming a first conductive layer 36 on the shielding metal layer 35 and forming a second conductive layer 37 on the second surface 11B.

The semiconductor structure 20 formed through the above steps is substantially the same as the semiconductor structure 20 shown in FIG. 2. The semiconductor structure 20 features a first doped region 31 and a second doped region 32 located beneath the first trench structure 21 and the second trench structure 22, respectively, as well as a third doped region 33 situated between the first trench structure 21 and the second trench structure 22. This configuration aims to increase the breakdown voltage and reduce the surface electric field.

The following provides further embodiments.

According to one aspect of the present disclosure, a semiconductor structure is provided that includes: a substrate comprising a first surface and a second surface relative to the first surface, a first trench structure extending from the first surface toward the second surface, wherein the first trench structure comprises a first polysilicon structure and a first oxide layer surrounding the first polysilicon structure, a shielding metal layer located on the first surface of the substrate and covering the first trench structure, a first conductive layer disposed on the shielding metal layer, and a second conductive layer disposed on the second surface of the substrate, wherein the substrate comprises a first doped region located between the first surface and the second surface, adjacent to the first oxide layer and separated from the first polysilicon structure.

Optionally, in any of the preceding aspects, the first oxide layer comprises a bottom wall portion and sidewall portions, with a thickness of the bottom wall portion being greater than a thickness of the sidewall portions.

Optionally, in any of the preceding aspects, at least a portion of the first oxide layer is located between the first polysilicon structure and the first doped region.

Optionally, in any of the preceding aspects, the first doped region has a first lower boundary, the first oxide layer has a second lower boundary, and the first polysilicon structure has a third lower boundary, wherein the first lower boundary, the second lower boundary, and the third lower boundary are configured to withstand a reverse voltage of the semiconductor structure.

Optionally, in any of the preceding aspects, the first doped region is located between the first oxide layer and the second surface.

Optionally, in any of the preceding aspects, the first polysilicon structure comprises a first portion and a second portion connected to the first portion, with a width of the second portion being greater than a width of the first portion, and the first portion and the second portion forming a stepped structure in a cross-sectional view of the semiconductor structure.

Optionally, in any of the preceding aspects, the first doped region has a first lower boundary, the first oxide layer has a second lower boundary, the first portion of the first polysilicon structure has a fourth lower boundary, and the second portion of the first polysilicon structure has a fifth lower boundary, wherein the first lower boundary, the second lower boundary, the fourth lower boundary, and the fifth lower boundary are configured to withstand a reverse voltage of the semiconductor structure.

Optionally, in any of the preceding aspects, the substrate comprises silicon carbide.

Optionally, in any of the preceding aspects, the semiconductor structure may further include: a second trench structure extending from the first surface toward the second surface, wherein the second trench structure comprises a second polysilicon structure and a second oxide layer surrounding the second polysilicon structure, wherein the substrate further comprises: a second doped region located between the first surface and the second surface, adjacent to the second oxide layer and separated from the second polysilicon structure, wherein a top surface of the second polysilicon structure and a top surface of the second oxide layer are coplanar with the first surface; and a third doped region located between the first trench structure and the second trench structure.

Optionally, in any of the preceding aspects, the third doped region extends from the first surface toward the second surface.

Optionally, in any of the preceding aspects, a distance from the first doped region to the first surface is greater than a distance from the third doped region to the first surface, and a distance from the second doped region to the first surface is greater than the distance from the third doped region to the first surface.

According to another aspect of the present disclosure, a manufacturing method for a semiconductor structure is provided that includes: forming a first trench and a second trench in a substrate, spaced apart from each other and extending from a first surface toward a second surface relative to the first surface; forming a first oxide layer in the first trench; forming a second oxide layer in the second trench; forming a first polysilicon structure in the first trench and surrounded by the first oxide layer, to form a first trench structure comprising the first polysilicon structure and the first oxide layer; and forming a second polysilicon structure in the second trench and surrounded by the second oxide layer, to form a second trench structure comprising the second polysilicon structure and the second oxide layer.

Optionally, in any of the preceding aspects, the manufacturing method may further include: forming a first doped region in the substrate, wherein the first doped region is adjacent to a bottom of the first trench; and forming a second doped region in the substrate, wherein the second doped region is adjacent to a bottom of the second trench.

Optionally, in any of the preceding aspects, the manufacturing method may further include: forming a third doped region in the substrate, wherein the third doped region is adjacent to the first surface and located between the first trench and the second trench.

Optionally, in any of the preceding aspects, the third doped region is formed before the first doped region and the second doped region are formed.

Optionally, in any of the preceding aspects, forming the first oxide layer in the first trench further includes: forming a bottom portion in the first trench; and forming sidewall portions in the first trench, located on top of the bottom portion.

Optionally, in any of the preceding aspects, the sidewall portions and the bottom portion collectively define a space, and the first polysilicon structure is formed within the space.

Optionally, in any of the preceding aspects, the space has a stepped structure in a cross-sectional view of the semiconductor structure, and the first polysilicon structure formed within the space also has a stepped structure in a cross-sectional view of the semiconductor structure.

Optionally, in any of the preceding aspects, the first trench structure and the second trench structure are formed simultaneously.

Optionally, in any of the preceding aspects, the manufacturing method may further include: forming a shielding metal layer on the first trench structure and the second trench structure; and forming a conductive layer on the shielding metal layer.

Features described in the context of one embodiment may be used in combination with other embodiments. For example, each of the optional features described above in the context of the apparatus may be used in combination with the method.

According to the structures and processes disclosed above, steps in the aforementioned processes can be adjusted or reordered while maintaining the same objectives and concepts, in order to achieve the same or similar semiconductor structures.

In this disclosure, spatial relative terms such as “below,” “beneath,” “lower,” “above,” “upper,” “left,” “right,” “on”, etc., are used to describe the relationships between one component or feature and one or more other components or features as depicted in the figures. Aside from the orientations depicted in the figures, these spatial relative terms are also intended to cover different operational orientations of the device. The device can be oriented in other ways (e.g., rotated 90 degrees or placed in other orientations), and the spatial relative descriptions used herein are intended to be interpreted correspondingly. It should be understood that when a component is said to be “connected to” or “coupled to” another component, it can be directly connected or coupled to the other component, or intervening components may be present.

As used herein, terms like “approximately,” “substantially,” and “about” are used to describe and account for small variations. When used in conjunction with an event or circumstance, these terms can refer to the precise occurrence of the event or circumstance as well as instances that are close to such occurrence. As used herein concerning given values or ranges, the term “about” generally means within ±10%, ±5%, ±1%, or ±0.5% of a given value or range. Ranges can be expressed as from one endpoint to another endpoint, or encompassing everything between two endpoints. All ranges disclosed herein include their endpoints unless otherwise specified. The term “substantially coplanar” may refer to two surfaces that are positioned along the same plane with a positional difference of a few micrometers (μm), such as within 10 μm, 5 μm, 1 μm, or 0.5 μm. When numerical values or characteristics are described as “substantially” the same, the terms may denote values within ±10%, ±5%, ±1%, or ±0.5% of the stated average value.

The foregoing content outlines several embodiments' features and the detailed aspects of this disclosure. The embodiments described herein can readily serve as the basis for designing or modifying other processes and structures to achieve similar purposes or to attain the advantages introduced by the embodiments discussed.

Although the description has been described in detail, it should be understood that various changes, substitutions and alterations can be made without departing from the spirit and scope of this disclosure as defined by the appended claims. Moreover, the scope of the disclosure is not intended to be limited to the particular embodiments described herein, as one of ordinary skill in the art will readily appreciate from this disclosure that processes, machines, manufacture, compositions of matter, means, methods, or steps, presently existing or later to be developed, which may perform substantially the same function or achieve substantially the same result as the corresponding embodiments described herein, may be utilized according to the present disclosure. Accordingly, the appended claims are intended to include within their scope such processes, machines, manufacture, compositions of matter, means, methods, or steps.

What is claimed is:

1. A semiconductor structure, comprising:
a substrate comprising a first surface and a second surface positioned on an opposite side of the substrate;
a first trench structure extending from the first surface toward the second surface, wherein the first trench structure comprises a first polysilicon structure and a first oxide layer surrounding the first polysilicon structure;
a shielding metal layer located on the first surface of the substrate and covering the first trench structure;
a first conductive layer disposed on the shielding metal layer; and
a second conductive layer disposed on the second surface of the substrate,
wherein the substrate comprises a first doped region located between the first surface and the second surface, adjacent to the first oxide layer and separated from the first polysilicon structure.

2. The semiconductor structure of claim 1, wherein a top surface of the first polysilicon structure and a top surface of the first oxide layer are coplanar with the first surface.

3. The semiconductor structure of claim 2, further comprising:
a second trench structure extending from the first surface toward the second surface, wherein the second trench structure comprises a second polysilicon structure and a second oxide layer surrounding the second polysilicon structure,
wherein the substrate further comprises:
a second doped region located between the first surface and the second surface, adjacent to the second oxide layer and separated from the second polysilicon structure, wherein a top surface of the second polysilicon structure and a top surface of the second oxide layer are coplanar with the first surface; and
a third doped region located between the first trench structure and the second trench structure.

4. The semiconductor structure of claim 3, wherein the third doped region extends from the first surface toward the second surface.

5. The semiconductor structure of claim 3, wherein a distance from the first doped region to the first surface is greater than a distance from the third doped region to the first surface, and a distance from the second doped region to the first surface is greater than the distance from the third doped region to the first surface.

6. The semiconductor structure of claim 1, wherein the first oxide layer comprises a bottom wall portion and sidewall portions, with a thickness of the bottom wall portion being greater than a thickness of the sidewall portions.

7. The semiconductor structure of claim 1, wherein the first doped region has a first lower boundary, the first oxide layer has a second lower boundary, and the first polysilicon structure has a third lower boundary, wherein the first lower boundary, the second lower boundary, and the third lower boundary are configured to withstand a reverse voltage of the semiconductor structure.

8. The semiconductor structure of claim 1, wherein the first doped region is located beneath the first trench structure and is in direct contact with the first oxide layer.

9. The semiconductor structure of claim 1, wherein the first polysilicon structure comprises an upper portion and a lower portion connected to the upper portion, with a width of the upper portion being greater than a width of the lower portion, and the upper portion and the lower portion forming a stepped structure in a cross-sectional view of the semiconductor structure.

10. The semiconductor structure of claim 9, wherein the first doped region has a first lower boundary, the first oxide layer has a second lower boundary, the lower portion of the first polysilicon structure has a fourth lower boundary, and the upper portion of the first polysilicon structure has a fifth lower boundary, wherein the first lower boundary, the second lower boundary, the fourth lower boundary, and the fifth lower boundary are configured to withstand a reverse voltage of the semiconductor structure.

11. The semiconductor structure of claim 1, wherein the substrate comprises silicon carbide.

12. A method for manufacturing a semiconductor structure, comprising:
forming a first trench and a second trench in a substrate, wherein the first trench and the second trench are spaced apart and extend from a first surface of the substrate toward a second surface of the substrate located on an opposite side of the substrate;
forming a first oxide layer in the first trench;
forming a second oxide layer in the second trench;
forming a first polysilicon structure in the first trench, wherein the first polysilicon structure is surrounded by the first oxide layer, and the first polysilicon structure and the first oxide layer form a first trench structure; and
forming a second polysilicon structure in the second trench, wherein the second polysilicon structure is surrounded by the second oxide layer, and the second polysilicon structure and the second oxide layer form a second trench structure.

13. The method of claim 12, further comprising:
forming a first doped region in the substrate, wherein the first doped region is adjacent to a bottom of the first trench; and
forming a second doped region in the substrate, wherein the second doped region is adjacent to a bottom of the second trench.

14. The method of claim 13, further comprising:
forming a third doped region in the substrate, wherein the third doped region is adjacent to the first surface and located between the first trench and the second trench.

15. The method of claim 14, wherein the third doped region is formed before the first doped region and the second doped region are formed.

16. The method of claim 12, wherein forming the first oxide layer in the first trench further comprises:
forming a bottom portion the first oxide layer of the in the first trench; and
forming sidewall portions of the first oxide layer in the first trench, located on top of the bottom portion.

17. The method of claim 16, wherein the sidewall portions and the bottom portion collectively define a space, and the first polysilicon structure is formed within the space.

18. The method of claim 17, wherein the first polysilicon structure formed within the space has a stepped structure in a cross-sectional view of the semiconductor structure, comprising an upper portion and a lower portion connected to the upper portion, with a width of the upper portion being greater than a width of the lower portion.

19. The method of claim 12, wherein the first trench structure and the second trench structure are formed simultaneously.

20. The method of claim 12, further comprising:
forming a shielding metal layer on the first trench structure and the second trench structure; and
forming a conductive layer on the shielding metal layer.
